(19) United States
(12) Patent Application Publication
(10) Pub. No.: US 2005/0094358 A1
(43) Pub. Date: May 5, 2005

(54) Information processing apparatus

(76) Inventor: Kiyoshi Shirato, Hyogo (JP)

Correspondence Address: WENDEROTH, LIND & PONACK, L.L.P., 2033 K STREET N. W., SUITE 800, WASHINGTON, DC, 20006-1021, US

(21) Appl. No.: 10/894,123

(22) Filed: Jul. 20, 2004

(30) Foreign Application Priority Data
Oct. 21, 2003 (JP) 2003-360229

(51) Int. Cl. H05K 7/00; H05K 7/16

(52) U.S. Cl. 361/679; 361/681; 361/680

(57) ABSTRACT

An information processing apparatus of the present invention has a salt-damage-proofing means. The salt-damage-proofing means is, for example, a coating applied to a part mainly containing magnesium in a casing, a coating applied to a printed circuit board, or a coating applied to a keyboard support board mainly containing aluminum. Providing the salt-damage-proofing means allows use in an environment where the apparatus is exposed to salt-laden water or atmosphere. High visibility allows accurate and speedy recognition of much data and performing of a next operation, and high operability allows comfortable input of much data at a high speed. The information processing apparatus is connected to another electronic apparatus via a cable, exchanges information via the cable, and can continuously receive stable power from the outside for a long time.

### BACKGROUND OF THE INVENTION

1. Field of the Invention

The present invention relates to an information processing apparatus used in an environment where the apparatus is exposed to salt-laden water or atmosphere such as sea water or salty wind. This environment is provided, for example, on a ship during berthing on the seashore or the sea or during traveling on the sea. The information processing apparatus is, for example, a stationary computer, a portable computer, a portable information terminal device, an electronic notebook, an electronic digital camera, a stationary communication device, a portable communication device, a mobile phone, a stationary position detection apparatus, a portable position detection apparatus, a device having a function included in two or more of the devices discussed above, or the other various devices.

2. Background Art

As an example of the information processing apparatus that can be used in an environment where the apparatus is exposed to salt-laden water or atmosphere, an electronic portable terminal device stored in a waterproof case is disposed in Japanese Patent Unexamined Publication No. 2002-287851.

In this conventional art, the electronic portable terminal device has no water proofing function in itself, but the normal electronic portable terminal device is stored in a waterproof case having a water proofing function.

This electronic device therefore has no water proofing means and no salt-damage proofing means.

FIG. 7 shows a sectional view of waterproof case 991 as an example of the waterproof case described in the conventional art, and a side view of portable information terminal device 993 as an example of the electronic portable terminal device stored in waterproof case 991.

Waterproof case window 992 is disposed in an upper part of waterproof case 991. Waterproof case window 992 is made of a material having transparency and elasticity such as polyester.

Waterproof case 991 is sealed, so that water or air does not infiltrate from the outside.

Portable information terminal device 993 is stored in waterproof case 991.

Operation unit 994 and display unit 995 of the portable information terminal device are disposed in the upper part of portable information terminal device 993 and at positions just under waterproof case window 992.

Operation unit 994 of the portable information terminal device is, for example, a keyboard switch used for turning on or off a power supply or inputting data. Display unit 995 of the portable information terminal device is, for example, a liquid crystal display for displaying data or a status.

Since waterproof case window 992 is made of the material having transparency, the user can recognize the data or status displayed on display unit 995 while securing sealing property of waterproof case 991.

Since waterproof case window 992 is also made of the material having elasticity, the user can operate the keyboard switch of operation unit 994 from the upside of waterproof case window 992 to turn on or off the power supply or input data, while securing sealing property of waterproof case 991.

As discussed above, in this conventional art, the electronic portable terminal device has no water proofing function in itself, but the normal electronic portable terminal device is stored in a waterproof case having a water proofing function.

This electronic device therefore has no water proofing means and no salt-damage proofing means.

The electronic portable terminal device stored in the conventional waterproof case naturally allows the operation of its operation unit, the turn on or off of the power supply, and inputting of the data, but these operations are performed through the window made of material having transparency and elasticity. Therefore, the operability is not so good, much data is difficult to be input comfortably and at a high speed, and this electronic portable terminal device cannot be used for these purposes.

Data or a status displayed on the display unit can be recognized, but the recognition is performed through the window made of the material having transparency and elasticity. Therefore, the visibility is not so good, it is difficult to recognize much data accurately and speedily and to perform a next operation, and this electronic portable terminal device cannot be used for these purposes.

In the electronic portable terminal device stored in the conventional waterproof case, the waterproof case has water proofing performance and salt-damage proofing performance and is hence sealed. Therefore, extracting of a cable from the electronic device stored in the case, connection and communication with another electronic device, or power supply from the outside is not allowed.

### SUMMARY OF THE INVENTION

An information processing apparatus of the present invention has at least one or more salt-damage-proofing means selected from the following elements:
a coating applied to a part mainly containing magnesium or aluminum in a casing;
a coating applied to a printed circuit board;
a coating applied to a keyboard support board;
a sealant applied to a hinge unit;
a connector socket tightly contacting with a counter connector plug during connection;
a coating applied to a metal contact part;
a sealing member applied to a joint part of the casing;
fibrous conductive cloth containing silver and carbon;
an extension connector coupled to a connector unit; and
a stainless steel screw.
   The information processing apparatus of the present invention has such a salt-damage-proofing means, so that the present invention can address a problem of the conventional information processing apparatus that can be used in an environment where the apparatus is exposed to salt-laden water or atmosphere. In other words, high visibility allows accurate and speedy recognition of much data and performing of a next operation, and high operability allows comfortable input of much data at a high speed.

### BRIEF DESCRIPTION OF THE DRAWINGS

FIG. 1 is a perspective view of an essential part of a notebook computer in accordance with an exemplary embodiment of the present invention.

FIG. 2 is an enlarged view of a hinge mechanism in accordance with the exemplary embodiment.

FIG. 3 is an enlarged view of an alternating current (AC) power supply socket in accordance with the exemplary embodiment.

FIG. 4 is an enlarged view of an AC power supply socket pin and an AC power supply plug pin in accordance with the exemplary embodiment.

FIG. 5 is a perspective view of the bottom surface and the back surface of the notebook computer in accordance with the exemplary embodiment.

FIG. 6 is an enlarged view of a connecting part between a connector socket and a connector plug in accordance with the exemplary embodiment.

FIG. 7 is a sectional view of a conventional waterproof case and a conventional portable information terminal device.

### DETAILED DESCRIPTION OF THE INVENTION

The present invention provides an information processing apparatus having at least one or more salt-damage-proofing means selected from the following salt-damage-proofing means:
a coating applied to a part mainly containing magnesium or aluminum in a casing;
a coating applied to a printed circuit board;
a coating applied to a keyboard support board;
a sealant applied to a hinge unit;
a connector socket tightly contacting with a counter connector plug during connection;
a coating applied to a metal contact part;
a sealing member applied to a joint part of the casing;
fibrous conductive cloth containing silver and carbon;
an extension connector coupled to a connector unit; and
a stainless steel screw.
   The salt-damage-proofing means of the present invention refers to both of a means for preventing infiltration of salt-laden water or atmosphere and a means for suppressing occurrence of corrosion even if salt-laden water infiltrates. The salt-damage-proofing means of the present invention do not therefore include the waterproof case described in the conventional example.

An exemplary embodiment of the present invention is described with reference to the drawings.

(Exemplary Embodiment)

A notebook computer as an example of the information processing apparatus of the present invention is described in the exemplary embodiment. However, the information processing apparatus of the present invention is not limited to the notebook computer. The information processing apparatus may be a stationary computer, a portable computer, a portable information terminal device, an electronic notebook, an electronic digital camera, a stationary communication device, a portable communication device, a portable phone, a stationary position detection apparatus, a portable position detection apparatus, a device having a function included in two or more of the devices discussed above, or the other various devices. An essential part of the present invention can be similarly applied to these devices, so that the notebook computer is described as an example and the other devices are not described.

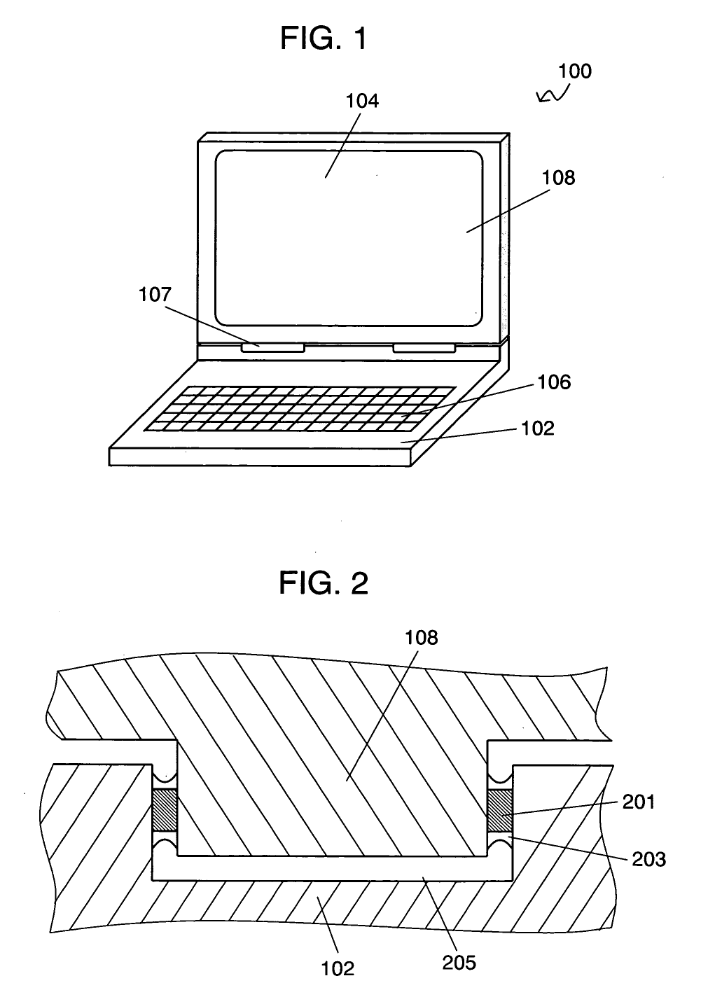

FIG. 1 is a perspective view of an essential part of notebook computer 100 in accordance with the present exemplary embodiment.

Notebook computer 100 can be mainly divided to a unit stored in body casing 102 as an exemplary embodiment of an operating unit of the present invention and a unit stored in display unit casing 108 as an exemplary embodiment of a display unit of the present invention.

The unit stored in body casing 102 has a main board (a printed circuit board, not shown) including a central processing unit (CPU) and a keyboard support board (not shown) including key units constituting keyboard 106 as an exemplary embodiment of an input means.

The unit stored in display unit casing 108 includes display panel 104 as an exemplary embodiment of a display means. Display panel 104 is a liquid crystal display unit, but may be a plasma display panel (PDP), a cathode ray tube (CRT), or the other information displaying means.

Body casing 102 is connected to display unit casing 108 through hinge mechanism 107.

Recently, body casing 102 of notebook computer 100 is often made of a magnesium alloy mainly containing magnesium or an aluminum alloy mainly containing aluminum.

The magnesium alloy is a material produced by mixing one or both of aluminum and zinc or the other metal into magnesium, and the alloy has strength and heat radiating performance higher than those of a conventional body casing made of resin.

The aluminum alloy is similar to the magnesium alloy, so that the magnesium alloy is described hereinafter as an example.

However, the magnesium alloy is apt to be corroded by salt contained in seawater or the like. In notebook computer 100 of the present embodiment, therefore, body casing 102 is made of the magnesium alloy and the surface thereof is covered with coating, so that the strength and heat radiating performance are kept high and salt-damage proofing performance is high.

The coating is made of, for example, acrylic resin, epoxy resin, or mixture of them. The acrylic resin has high weather resistance, and the epoxy resin has high chemical resistance and is effect as a protective coating against salt. A mixture of a plurality of resins having the good property has higher performance as a coating resin for a marine apparatus.

Applying the resin or the mixture of the resins allows formation of a coating with thickness of 10 μm to 150 μm. Usual coating methods such as spray coating or dipping can be used. Film made of the resin may be produced in advance, and may be adhered to a desired surface via an adhesive or the like.

When the coating is too thick, heat radiating performance is decreased. When the thickness of the coating is between 20 μm and 80 μm, the higher performance can be obtained. When the thickness of the coating is between 30 μm and 50 μm, a further higher performance can be obtained.

This coating may be applied to the outer surface of body casing 102 of notebook computer 100. Also, the coating may be applied to the whole surfaces including the inner surface to produce a higher performance.

The material of body casing 102 and the application of the coating thereof have been described; however, the same material may be used for display unit casing 108 and the application of the coating thereof may be also used, and similar improved performance to those of body casing 102 may be obtained. Otherwise, display unit casing 108 may have a different structure.

As discussed above, body casing 102 has a built-in main board including a CPU and other built-in boards (a printed circuit board, and so on, not shown).

In the present embodiment, covering the main board and the other built-in boards with coating further improves the salt-damage proofing performance.

The printed circuit board includes various electronic components and is stored in the body casing, so that the printed circuit board is not directly exposed to the outside air and is not splashed with seawater. However, the printed circuit board can have indirect influence of the outside air and the seawater. The coating is used for minimizing the influence on the various electronic components.

As the material of the coating for covering the printed circuit board, for example, polyurethane resin can be used. Solution of the resin is sprayed or dipped, thereby forming a coating having thickness of 10 to 150 μm.

The property of the coating is similar to that of the coating applied to body casing 102 made of the magnesium alloy. In other words, too thick coating reduces heat radiating performance, and setting the thickness at a value between 20 μm and 80 μm or between 30 μm and 50 μm can produce the higher performance.

Additionally, similarly to body casing 102, the salt-damage proofing performance is improved by covering not only the front surface of the printed circuit board but also the back surface.

The whole surfaces of all printed circuit boards are not required to be covered, but only part of the surfaces may be covered.

Only various printed circuit boards, built in body casing 102, have been described. However, display unit casing 108 also can have built-in printed circuit boards, and these printed circuit boards may be covered with similar coating. The description of them is omitted because the detail is similar.

In the notebook computer of the present invention, the keyboard support board including key units constituting keyboard 106 is covered with a similar coating.

The keyboard support board is often made of a material mainly containing aluminum in consideration of the strength and weight saving. However, this material mainly containing aluminum is apt to be extremely corroded by salt contained in seawater or the like.

The keyboard support board, similarly to the various printed circuit boards, is disposed in body casing 102 of notebook computer 100, but air or water can infiltrate from a clearance of an operation part of each key unit of keyboard 106.

The keyboard support board is covered with a similar coating to achieve the strength and lightening and to prevent corrosion by salt.

The forming method of the coating and the other details are the same as those of the coating applied to the printed circuit boards or body casing 102, so that the description of them is omitted.

As discussed above, body casing 102 is connected to display unit casing 108 through hinge mechanism 107 as one embodiment of a hinge unit of the present invention.

FIG. 2 is an enlarged view of the hinge mechanism.

Two same hinge mechanisms 107 for rotatably connecting body casing 102 to display unit casing 108 exist right and left in the present embodiment, as shown in FIG. 1. FIG. 2 shows one of hinge mechanisms 107.

In FIG. 2, the upper section is a part of display unit casing 108 constituting hinge mechanism 107, and the lower section is a part of body casing 102 constituting hinge mechanism 107.

The part of display unit casing 108 constituting hinge mechanism 107 is faced to the part of body casing 102 constituting hinge mechanism 107 with clearance 205 sandwiched.

The part of display unit casing 108 constituting hinge mechanism 107 is connected to the part of body casing 102 constituting hinge mechanism 107 through connecting rod 201 passing through clearance 205.

Connecting rod 201 is columnar, and body casing 102 and display unit casing 108 can be rotate circumferentially.

Sections around connecting rod 201 where connecting rod 201 passes through holes formed in body casing 102 and display unit casing 108 are sealed by grease 203.

Grease 203 prevents the seawater or outside air from infiltrating into body casing 102 or display unit casing 108 from the clearances between connecting rod 201 and the holes. The holes are formed in body casing 102 and display unit casing 108 that pass connecting rod 201.

Notebook computer 100 has a connector unit (a connector socket) for connecting notebook computer 100 to another apparatus or an AC power supply.

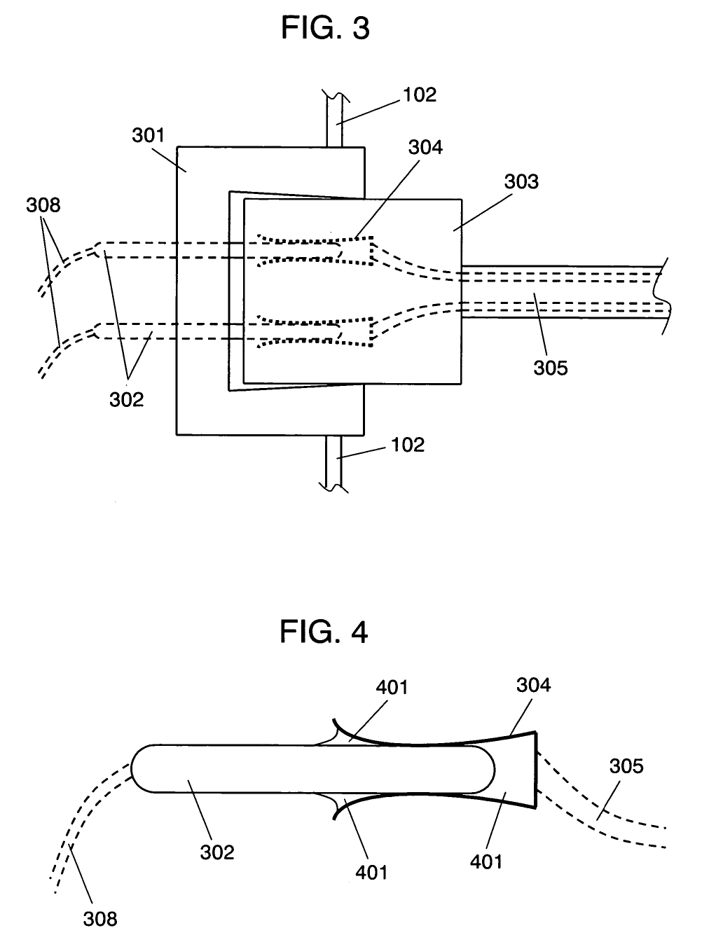

FIG. 3 is an enlarged view of AC power supply socket 301 as one embodiment, AC power supply plug 303 to be connected to AC power supply socket, and their peripheries.

AC power supply (connector) socket 301 and AC power supply (connector) plug 303 that are used for connection to the AC power supply are hereinafter described as an example of the connector unit. An electric connector for communicating other various signals is similarly handled.

As shown in FIG. 3, AC power supply socket 301 is mounted to body casing 102.

AC power supply socket 301 includes AC power supply socket pins 302 used for electric connection and current flow. Power is supplied from AC power supply socket pins 302 to each circuit, apparatus, component, or printed circuit board in body casing 102 through AC power supply cables 308.

AC power supply socket 301 is engaged with AC power supply plug 303.

AC power supply cord 305 is connected to AC power supply plug 303, and hence AC power is supplied to AC power supply plug pins 304 in AC power supply plug 303 through AC power supply cord 305.

When AC power supply socket 301 is engaged with AC power supply plug 303, AC power supply socket pins 302 are engaged with AC power supply plug pins 304 to supply power from AC power supply plug pins 304 to AC power supply socket pins 302.

As shown in FIG. 3, the surfaces of AC power supply socket 301 engaging with AC power supply plug 303 tilt inward gradually from the deep part to the shallow part of AC power supply socket 301.

The tilting angle is not generally so large.

One or both of AC power supply socket 301 and AC power supply plug 303 are made of an elastic member. Rubber or elastic polymer may be used as the elastic member.

Therefore, when AC power supply plug 303 is pressed into AC power supply socket 301, the shallow part of AC power supply socket 301 that tilts inward is pressed outward or AC power supply plug 303 is pressed inward. Thus, AC power supply plug 303 is pressed into AC power supply socket 301, and AC power supply socket pins 302 are engaged with AC power supply plug pins 304.

Even if AC power supply plug 303 is pressed inward, it returns to its original size inside AC power supply socket 301 when AC power supply plug 303 is completely pressed into AC power supply socket 301 and AC power supply socket pins 302 are completely engaged with AC power supply plug pins 304. That is because the deep part of AC power supply socket 301 is larger than the shallow part thereof.

Thus, AC power supply socket 301 is tightly fitted in AC power supply plug 303, so that seawater or the outside air does not infiltrate into body casing 102 through the clearance between them.

FIG. 4 shows an enlarged view of each AC power supply socket pin 302 and each AC power supply plug pin 304 that are engaged with each other.

In FIG. 4, elements denoted with the same reference numbers as those of FIG. 3 have been already described, so that the descriptions of those elements are omitted.

In the embodiment shown in FIG. 4, respective engaging metal parts of AC power supply socket pin 302 and AC power supply plug pin 304 are coated with contact oil 401.

The contact oil is oily and rejects seawater, and hence can prevent an accident that the seawater or the outside air contacts with AC power supply socket pins 302 and AC power supply plug pins 304 to corrode them.

Contact oil 401 reduces oxidized metal, keeps conductive performance to be highly efficient, and removes soil and refuse adhered to the metal, so that contact oil 401 can improve efficiency of current flow from AC power supply plug pins 304 to AC power supply socket pins 302.

One or both of body casing 102 and display unit casing 108 of notebook computer 100 of the present embodiment have a structure (not shown) having two or more divided units.

In other words, body casing 102 or display unit casing 108 is assembled by storing components or the like while two or more units are divided, and then coupling the divided units to each other.

In assembling body casing 102 or display unit casing 108, one or a plurality of stainless steel screws (not shown) resistant to corrosion by salt or the like is used. The whole screw does not need to be made of stainless steel, only a part directly exposed to the seawater or the outside air may be made of stainless steel.

At a repair or inspection time, body casing 102 or display unit casing 108 is disassembled and assembled again as described above.

Packing (not shown) as a sealing member is sandwiched between two or more units of one or both of body casing 102 and display unit casing 108. The packing is used for preventing the seawater or the outside air from infiltrating into body casing 102 and display unit casing 108 through a clearance between the two or more units and from corroding the insides of them.

As the packing, a fibrous sealing member containing silver and carbon is used.

The packing formed of this fibrous sealing member has extremely high resistance to salt contained in the seawater or the like and is not corroded by the seawater or the like. Additionally, this fibrous form allows extreme improvement of air-tightness.

One or both of body casing 102 and display unit casing 108 of notebook computer 100 of the present embodiment have many built-in printed circuit boards, apparatuses, or components.

These apparatuses or components may generate undesired radiation of electromagnetic noise, so that measures must be taken against leakage of the undesired radiation from the notebook computer.

For preventing the leakage of the undesired radiation, conductive cloth containing silver and carbon is used (not shown), and a part that generates or can generate the undesired radiation is covered with the conductive cloth (not shown), in the present embodiment.

The conductive cloth containing silver and carbon additionally has high resistance to salt contained in the seawater or the like. Therefore, even if the seawater or the outside air containing salt infiltrates into body casing 102 or display unit casing 108 of notebook computer 100, the conductive cloth is not corroded and the inside covered with the conductive cloth is not corroded.

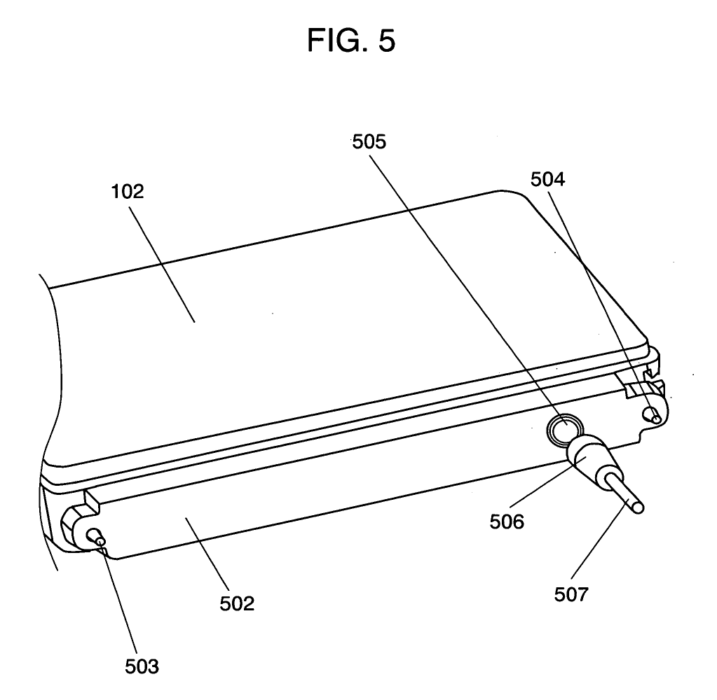

FIG. 5 is a perspective view of the bottom surface and the back surface of notebook computer 100 in accordance with the embodiment.

In FIG. 5, body casing 102 of notebook computer 100 shown in FIG. 1 is illustrated in the view in the oblique direction between the bottom surface and the back surface.

Many connector sockets are installed in the back surface of body casing 102.

These connector sockets are used for connecting cables or the like to the other apparatuses or networks. For example, the connector sockets are used for connection of a printer, are subject to general USB (Universal Serial Bus, namely a standard determined by USB Implementers Forum, Inc.), are subject to a standard such as 10BASE-T (one of IEEE802.3 as the <Ethernet> standard) for connection to a network, or are the other various connector sockets.

When many connector sockets are thus exposed, however, the possibility that salt contained in the seawater infiltrates through the connecting part increases.

In notebook computer 100 of the present embodiment, extension connector unit 502 is installed in the back surface of body casing 102. Body casing 102 covers many connector sockets, and involves connector socket 505 which collects all cables for signal communication and power supply connecting from the connector sockets to the other apparatuses as a conversion connector socket. Connector socket 505 as the conversion connector socket is engaged with connector plug 506 to be connected to cable 507 connecting to the external apparatus.

Extension connector unit 502 is fixed to the back surface of body casing 102 through a salt-damage-proofing and water-proofing packing made of a salt-damage-proofing material by screw 503 and screw 504 for pressure contact, so that salt contained in the seawater or the like does not infiltrate through a clearance between body casing 102 and extension connector unit 502.

Extension connector unit 502 covers all of many various connector sockets disposed in the back surface of body casing 102. Therefore, salt contained in seawater or the like does not infiltrate through engaging parts between many various connector sockets.

Extension connector unit 502 covers all of many various connector sockets disposed in the back surface of body casing 102 in the above description; however, all of them are not necessarily covered, but only part of the connector sockets may be covered if necessary.

Only one extension connector unit 502 is disposed in the back surface of body casing 102 in the above description; however, the present invention is not always limited to one extension connector unit. Two or more extension connector units 502 may be disposed and may cover all or part of the various connector sockets.

Only one connector socket 505 is disposed in the extension connector unit and is used for connection to the outside in the above description; however, the present invention is not always limited to one. Two or more connector sockets 505 may be disposed and may connect the notebook computer to the other apparatus.

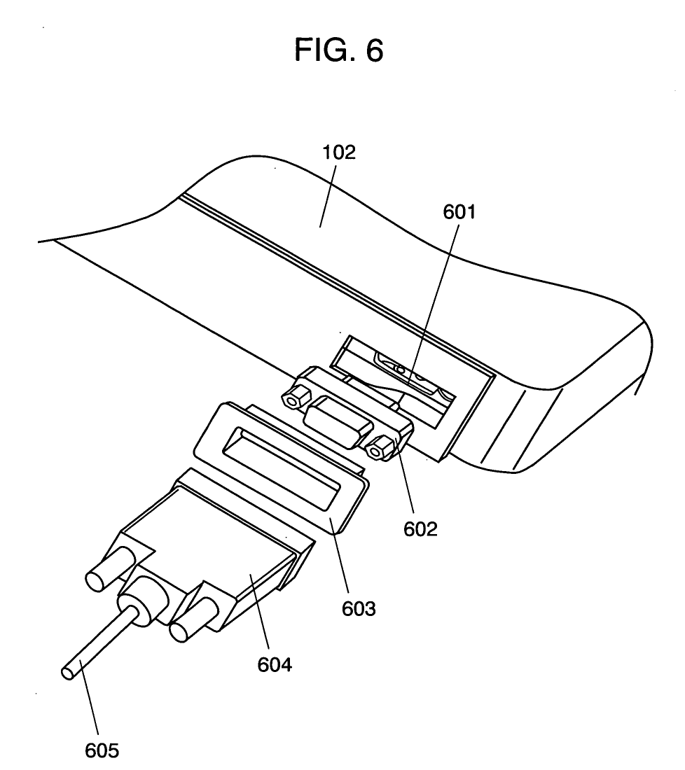

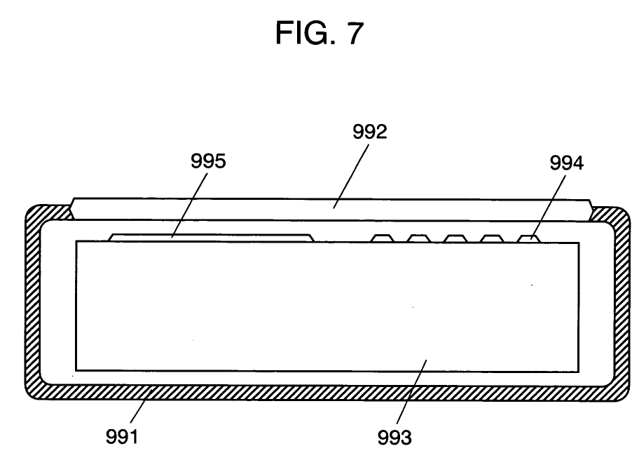

FIG. 6 is an enlarged view of a connecting part between connector socket and connector plug.

Extension connector socket 602 of FIG. 6 corresponds to connector socket 505 of FIG. 5, and connector plug 604 of FIG. 6 corresponds to connector plug 506 of FIG. 5.

Connector socket 505 and connector plug 506 of FIG. 5 are of a round type, and extension connector socket 602 and connector plug 604 of FIG. 6 are of a square type. Only one of two types does not need to be selected, but either of them may be used. The type thereof is irrelevant to an essential part of the present invention.

Extension connector socket 602 of FIG. 6 corresponds to connector socket 505 disposed in extension connector unit 502 in the above description; however, extension connector socket 602 may be a connector socket to be disposed in the back surface of body casing 102.

When extension connector socket 602 is the connector socket to be disposed in the back surface of body casing 102, the connector socket may be exposed to the outside without being covered with extension connector unit 502, or may be covered with extension connector unit 502.

Extension connector socket 602 is connected to various connector sockets in extension connector unit 502 or to various components in body casing 102 through internal cable 601.

Extension connector socket 602 may be connected to one of various connector sockets disposed in the back surface of body casing 102, and may be used for extracting the connector socket to the outside.

In this case, if this connector socket is corroded by salt contained in the seawater or the like, only extracted extension connector socket 602 is replaced by another socket to facilitate the repair.

Extension connector socket 602 is engaged with connector plug 604 via waterproof packing 603, and is connected to another apparatus through cable 605 connecting to connector plug 604.

Waterproof packing 603 is inserted into an engaging part between extension connector socket 602 and connector plug 604, and waterproof packing 603 is made of a salt-resistant material, so that salt contained in the seawater or the like does not infiltrate through the engaging part between extension connector socket 602 and connector plug 604.

In the case where extension connector socket 602 has a structure where various connectors disposed in the back surface of body casing 102 are extracted to the outside, even if salt contained in the seawater or the like infiltrates through the engaging part, only extension connector socket 602 is needed to be replaced by another socket, which enables prompt repair.

As discussed above, the information processing apparatus of the present invention has various salt-damage-proofing means, thereby providing water-proofing and salt-damage-proofing function for the information processing apparatus itself. The salt-damage-proofing means may be individually used, or all of the salt-damage-proofing means may be used simultaneously.

As case window 992 is omitted, high visibility of the display is secured and much data can be accurately and speedily recognized. Consequently, continuous operation becomes possible. Comparing with the conventional art, the operability is high and much data can be input comfortably at a high speed. Additionally, while the salt-damage-proofing function is kept, the information processing apparatus can be connected to another electronic apparatus through a cable, information exchange can be performed via the cable, or power can be supplied from the outside continuously for a long time. The industrial applicability of the information processing apparatus is extremely high.

1. An information processing apparatus having a salt-damage-proofing means.

2. An information processing apparatus according to claim 1, wherein the salt-damage-proofing means is a coating applied to a part of a casing, the part mainly containing magnesium or aluminum.

3. An information processing apparatus according to claim 1, wherein the salt-damage-proofing means is a coating applied to a printed circuit board.

4. An information processing apparatus according to claim 1, wherein the salt-damage-proofing means is a coating applied to a support board of a keyboard.

5. An information processing apparatus according to claim 4, wherein the support board of the keyboard mainly contains aluminum.

6. An information processing apparatus according to claim 1, comprising a display unit having display means and an operation unit having input means,
wherein the display unit and the operation unit are rotatably joined to each other through a hinge unit, and the salt-damage-proofing means is a sealant applied to the hinge unit.

7. An information processing apparatus according to claim 1, comprising a connector socket for electrically coupling the information processing apparatus to another apparatus,
wherein the salt-damage-proofing means is the connector socket tightly contacting with a counter connector plug during the coupling.

8. An information processing apparatus according to claim 7, wherein the connector socket and the connector plug are a connector socket and a connector plug for power supply.

9. An information processing apparatus according to claim 1, wherein the salt-damage-proofing means is a coating applied to a metal contact part.

10. An information processing apparatus according to claim 9, wherein the coating applied to the metal contact part is reducer oil.

11. An information processing apparatus according to claim 1, wherein the salt-damage-proofing means is a first sealing member applied to a joint part of the casing.

12. An information processing apparatus according to claim 11, wherein the first sealing member is a fibrous sealing member containing silver and carbon.

13. An information processing apparatus according to claim 1, wherein the salt-damage-proofing means is fibrous conductive cloth containing silver and carbon.

14. An information processing apparatus according to claim 1, wherein the salt-damage-proofing means is a stainless steel screw.

15. An information processing apparatus according to claim 1, wherein the salt-damage-proofing means is an extension connector connected to a connector unit of the information processing apparatus.

16. An information processing apparatus according to claim 15, wherein the extension connector is connected to a cable via a second sealing member.

17. An information processing apparatus according to claim 15,
wherein the extension connector is a conversion connector formed by integrating connection terminals included in a plurality of connectors of the information processing apparatus and storing the connection terminals in a connector socket.

18. An information processing apparatus according to claim 15,
wherein the conversion connector is disposed in an extension unit, and the extension unit is connected to the information processing apparatus via a third sealing member.

19. An information processing apparatus according to claim 1,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

20. An information processing apparatus comprising at least one or more means selected from various means,
the various means including:
a coating applied to a part mainly containing magnesium or aluminum in a casing;
a coating applied to a printed circuit board;
a coating applied to a keyboard support board;
a sealant applied to a hinge unit;
a connector socket tightly contacting with a counter connector plug during connection;
a coating applied to a metal contact part;
a sealing member applied to a joint part of the casing;
fibrous conductive cloth containing silver and carbon;
an extension connector coupled to a connector unit; and
a stainless steel screw.

21. An information processing apparatus comprising:
a coating applied to a part mainly containing magnesium or aluminum in a casing;
a coating applied to a printed circuit board;
a coating applied to a keyboard support board;
a sealant applied to a hinge unit;
a connector socket tightly contacting with a counter connector plug during connection;
a coating applied to a metal contact part;
a sealing member applied to a joint part of the casing;
fibrous conductive cloth containing silver and carbon;
an extension connector coupled to a connector unit; and
a stainless steel screw.

22. An information processing apparatus according to claim 16,
wherein the conversion connector is disposed in an extension unit, and the extension unit is connected to the information processing apparatus via a third sealing member.

23. An information processing apparatus according to claim 17,
wherein the conversion connector is disposed in an extension unit, and the extension unit is connected to the information processing apparatus via a third sealing member.

24. An information processing apparatus according to claim 2,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

25. An information processing apparatus according to claim 3,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

26. An information processing apparatus according to claim 4,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

27. An information processing apparatus according to claim 5,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

28. An information processing apparatus according to claim 6,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

29. An information processing apparatus according to claim 7,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

30. An information processing apparatus according to claim 8,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

31. An information processing apparatus according to claim 9,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

32. An information processing apparatus according to claim 10,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

33. An information processing apparatus according to claim 11,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

34. An information processing apparatus according to claim 12,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

35. An information processing apparatus according to claim 13,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

36. An information processing apparatus according to claim 14,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.

37. An information processing apparatus according to claim 15,
wherein the information processing apparatus is one of at least one selected from various devices and a combined device of two or more of the various devices, the various devices comprising:
a stationary computer;
a portable computer;
a portable information terminal device;
an electronic notebook;
an electronic digital camera;
a stationary communication device;
a portable communication device;
a portable phone;
a stationary position detection apparatus; and
a portable position detection apparatus.
